(19) United States
(12) Patent Application Publication
(10) Pub. No.: US 2010/0220779 A1
(43) Pub. Date: Sep. 2, 2010

(54) COMMON BROADCAST RECEIVER AND METHOD FOR PROCESSING A RECEIVED SIGNAL THEREOF

(75) Inventors: Yong-sik KWON, Suwon-si (KR); Hae-joo JEONG, Seoul (KR); June-hee LEE, Seongnam-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSANG ELECTRONICS CO., LTD., Suwon-si (KR)

(21) Appl. No.: 12/604,441

(22) Filed: Oct. 23, 2009

(30) Foreign Application Priority Data
Feb. 27, 2009 (KR) 10-2009-0017270

(51) Int. Cl. H04L 27/06; H03K 5/159; H03M 13/05; G06F 11/10

(52) U.S. Cl. 375/232; 375/340; 714/752; 714/E11.032

(57) ABSTRACT

A common broadcast receiver that receives cable broadcast, terrestrial broadcast, and mobile broadcast signals is provided. The common broadcast receiver includes a synchronizer for receiving any one of a cable broadcast signal, a terrestrial broadcast signal, and a mobile broadcast signal including a training signal generated by a Deterministic Trellis Reset (DTR) and inserted in a data region, and synchronizing the received broadcast signal; and a signal detector for detecting any one of the cable broadcast signal, the terrestrial broadcast signal, and the mobile broadcast signal from the synchronized broadcast signal. Hence, the mobile broadcast signal can be received and processed in addition to the cable broadcast signal and the terrestrial broadcast signal.

### CROSS-REFERENCE TO RELATED APPLICATIONS

This application claims priority from Korean Patent Application No. 10-2009-17270, filed on Feb. 27, 2009, in the Korean Intellectual Property Office, the disclosure of which is incorporated herein by reference in its entirety.

### BACKGROUND OF THE INVENTION

1. Field of the Invention

Apparatuses and methods consistent with the present invention relate to a common broadcast receiver and a method for receiving a broadcast signal, and more particularly, to a broadcast receiver for receiving and processing a cable broadcast signal, a terrestrial broadcast signal, and a mobile broadcast signal all together, and a method for processing the received signals.

2. Description of the Related Art

Thanks to the advance of digital technologies, digital video processing systems, such as digital TVs, are widely provided. In addition, various digital broadcasting standards for processing the digital broadcast signals are suggested.

Among the various digital broadcasting standards, in the digital broadcasting of the U.S.A., the terrestrial broadcasting conforms to ATSC A. 53 (8-VSB) broadcasting standard and the cable broadcasting confirms to ITU-T J. 83 (QAM scheme) broadcasting standard.

Digital broadcasting allows for high-quality broadcasting and features higher propagation efficiency than analog broadcasting, to thus transmit and receive more information. Disadvantageously, digital broadcasting suffers from broadcast interruption when the transport stream is compromised by an ambient magnetic field or obstacle.

Recently, the above-stated problem has gotten worse in various mobile devices such as cellular phones, PDAs, PMPs, and MP3 players, receiving digital broadcasts. In this respect, ATSC Mobile/Handheld (M/H) broadcasting standard has been introduced for digital broadcasting using mobile devices in the U.S.A.

In this regard, a common receiver is needed for receiving and detecting cable broadcasts, terrestrial broadcasts, and mobile broadcasts.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above.

The present invention provides a common broadcast receiver for receiving a cable broadcast signal, a terrestrial broadcast signal, and a mobile broadcast signal all together, and a broadcast receiving method thereof.

Consistent with an aspect of the present invention, a common broadcast receiver for receiving and processing a plurality of broadcast signals, includes a synchronizer for receiving any one of a cable broadcast signal, a terrestrial broadcast signal, and a mobile broadcast signal including a training signal generated by a Deterministic Trellis Reset (DTR) and inserted in a data region, and synchronizing the received broadcast signal; and a signal detector for detecting any one of the cable broadcast signal, the terrestrial broadcast signal, and the mobile broadcast signal from the synchronized broadcast signal.

The signal detector may include a broadcasting mode determiner for determining which one of the cable broadcast signal, the terrestrial broadcast signal, and the mobile broadcast signal is the synchronized broadcast signal; an equalizer for equalizing the synchronized broadcast signal according to the determined broadcasting mode; and an Forward Error Correction (FEC) part for correcting error of the equalized signal.

The equalizer and the FEC part each may include a plurality of equalizers and a plurality of FEC parts corresponding to the cable broadcast signal, the terrestrial broadcast signal, and the mobile broadcast signal respectively.

The equalizer and the FEC part each may include a common equalizer and a common FEC part capable of processing the cable broadcast signal, the terrestrial broadcast signal, and the mobile broadcast signal all together.

The broadcasting mode determiner may determine the synchronized broadcast signal as the cable broadcast signal when a 1-byte sync signal is repeatedly detected from the synchronized broadcast signal in a preset cycle.

The broadcasting mode determiner may determine the synchronized broadcast signal as the cable broadcast signal when a field sync signal region is not detected from the synchronized broadcast signal.

The broadcasting mode determiner may determine that the field sync signal region is detected when the synchronized broadcast signal includes any one of a Pseudo Noise (PN) sequence in a preset form, a Vestigial SideBand (VSB) mode, and a reserved region.

The broadcasting mode determiner may determine the synchronized broadcast signal as the mobile broadcast signal when a training signal is inserted to a data region of the synchronized broadcast signal.

The broadcasting mode determiner may determine whether the synchronized broadcast signal is either the terrestrial broadcast signal or the mobile broadcast signal, according to a feature code value in a field sync signal region of the synchronized broadcast signal.

The broadcasting mode determiner may determine the synchronized broadcast signal as the mobile broadcast signal when a PN sequence in a preset size exists in a reserved region of a field sync signal region of the synchronized broadcast signal.

The broadcasting mode determiner may determine the synchronized broadcast signal as the mobile broadcast signal when a FEC coding is performed on symbols of a preset size in a reserved region of a field sync signal region of the synchronized broadcast signal.

The broadcasting mode determiner may assume that the synchronized broadcast signal is either the terrestrial broadcast signal or the mobile broadcast signal, output an error-corrected signal when the error-corrected signal is a normal signal, and modify the assumption and carry out the equalization and the error correction in order when the error-corrected signal is an error signal.

The signal detector may include an equalizer for equalizing the synchronized broadcast signal; a broadcasting mode determiner for determining which one of the cable broadcast signal, the terrestrial broadcast signal, and the mobile broadcast signal is the equalized broadcast signal; and an FEC part for correcting error according to the determined broadcast signal.

The broadcasting mode determiner may determine whether the equalized broadcast signal is the cable broadcast signal according to a constellation of the equalized broadcast signal.

The broadcasting mode determiner may determine the equalized broadcast signal as the cable broadcast signal when a 1-byte sync signal is repeatedly detected from the equalized broadcast signal in a preset cycle.

The broadcasting mode determiner may determine the equalized broadcast signal as the cable broadcast signal when a field sync signal region is not detected from the equalized broadcast signal.

The broadcasting mode determiner may determine that the field sync signal region is detected, when the equalized broadcast signal includes any one of a PN sequence in a preset form, a VSB mode, and a reserved region.

The broadcasting mode determiner may determine the equalized broadcast signal as the mobile broadcast signal when a training signal is inserted to a data region of the equalized broadcast signal.

The broadcasting mode determiner may determine whether the equalized broadcast signal is either the terrestrial broadcast signal or the mobile broadcast signal, according to a feature code value in a field sync signal region of the equalized broadcast signal.

The broadcasting mode determiner may determine the equalized broadcast signal as the mobile broadcast signal when a PN sequence of a preset size exists in a reserved region of a field sync signal region of the equalized broadcast signal.

The broadcasting mode determiner may determine the equalized broadcast signal as the mobile broadcast signal when a FEC coding is performed on symbols of a preset size in a reserved region of a field sync signal region of the equalized broadcast signal.

The broadcasting mode determiner may assume that the equalized broadcast signal is either the terrestrial broadcast signal or the mobile broadcast signal, output an error-corrected signal when the error-corrected signal is a normal signal, and modify the assumption and carry out the equalization and the error correction in order when the error-corrected signal is an error signal.

Consistent with another aspect of the present invention, a method for processing a received signal of a common broadcast receiver which receives and processes a plurality of broadcast signals, includes receiving any one of a cable broadcast signal, a terrestrial broadcast signal, and a mobile broadcast signal including a training signal generated by a DTR and inserted in a data region, and synchronizing the received broadcast signal; and detecting any one of the cable broadcast signal, the terrestrial broadcast signal, and the mobile broadcast signal from the synchronized broadcast signal.

The detecting operation may include determining which one of the cable broadcast signal, the terrestrial broadcast signal, and the mobile broadcast signal is the synchronized broadcast signal; equalizing the synchronized broadcast signal according to the determined broadcasting mode; and correcting error of the equalized signal.

The determining operation may determine the synchronized broadcast signal as the cable broadcast signal when a 1-byte sync signal is repeatedly detected from the synchronized broadcast signal in a preset cycle.

The determining operation may determine the synchronized broadcast signal as the cable broadcast signal when a field sync signal region is not detected from the synchronized broadcast signal.

The determining operation may determine that the field sync signal region is detected when the synchronized broadcast signal includes any one of a PN sequence in a preset form, a VSB mode, and a reserved region.

The determining operation may determine the synchronized broadcast signal as the mobile broadcast signal when a training signal is inserted to a data region of the synchronized broadcast signal.

The determining operation may determine whether the synchronized broadcast signal is either the terrestrial broadcast signal or the mobile broadcast signal, according to a feature code value in a field sync signal region of the synchronized broadcast signal.

The determining operation may determine the synchronized broadcast signal as the mobile broadcast signal when a PN sequence in a preset size exists in a reserved region of a field sync signal region of the synchronized broadcast signal.

The determining operation may determine the synchronized broadcast signal as the mobile broadcast signal when a FEC coding is performed on symbols of a preset size in a reserved region of a field sync signal region of the synchronized broadcast signal.

The determining operation may assume that the synchronized broadcast signal is either the terrestrial broadcast signal or the mobile broadcast signal, output an error-corrected signal when the error-corrected signal is a normal signal, and modify the assumption and carry out the equalization and the error correction in order when the error-corrected signal is an error signal.

The detecting operation may include equalizing the synchronized broadcast signal; determining which one of the cable broadcast signal, the terrestrial broadcast signal, and the mobile broadcast signal is the equalized broadcast signal; and correcting error according to the determined broadcast signal.

The determining operation may determine whether or not the equalized broadcast signal is the cable broadcast signal according to a constellation of the equalized broadcast signal.

The determining operation may determine the equalized broadcast signal as the cable broadcast signal when a 1-byte sync signal is repeatedly detected from the equalized broadcast signal in a preset cycle.

The determining operation may determine the equalized broadcast signal as the cable broadcast signal when a field sync signal region is not detected from the equalized broadcast signal.

The determining operation may determine that the field sync signal region is detected, when the equalized broadcast signal includes any one of a PN sequence in a preset form, a VSB mode, and a reserved region.

The determining operation may determine the equalized broadcast signal as the mobile broadcast signal when a training signal is inserted to a data region of the equalized broadcast signal.

The determining operation may determine whether the equalized broadcast signal is either the terrestrial broadcast signal or the mobile broadcast signal, according to a feature code value in a field sync signal region of the equalized broadcast signal.

The determining operation may determine the equalized broadcast signal as the mobile broadcast signal when a PN sequence of a preset size exists in a reserved region of a field sync signal region of the equalized broadcast signal.

The determining operation may determine the equalized broadcast signal as the mobile broadcast signal when a FEC coding is performed on symbols of a preset size in a reserved region of a field sync signal region of the equalized broadcast signal.

The determining operation may assume that the equalized broadcast signal is either the terrestrial broadcast signal or the mobile broadcast signal, output an error-corrected signal when the error-corrected signal is a normal signal, and modify the assumption and carry out the equalization and the error correction in order when the error-corrected signal is an error signal.

Additional and/or other aspects of the invention will be set forth in part in the description which follows and, in part, will be obvious from the description, or may be learned by practice of the invention.

### BRIEF DESCRIPTION OF THE DRAWING FIGURES

The above and/or other aspects of the present invention will be more apparent by describing certain exemplary embodiments of the present invention with reference to the accompanying drawings, in which:

FIG. 1 is a diagram of a common broadcast receiver according to an exemplary embodiment of the present invention;

FIG. 2 is a diagram of a cable broadcast signal;

FIG. 3 is a diagram of a terrestrial broadcast signal;

FIG. 4 is a diagram of a mobile broadcast signal;

FIGS. 5A and 5B are diagrams of a field sync region of the terrestrial broadcast signal and the mobile broadcast signal;

FIG. 6 is a diagram of a 63 PN sequence generator;

FIG. 7 is a diagram of a 511 PN sequence generator;

FIG. 8 is a diagram of a 127 PN sequence generator;

FIG. 9 is a diagram of a transmitter for transmitting the mobile broadcast signal from a transmitting side to a receiving side;

FIG. 10 is a detailed diagram of a digital broadcast transmitter of FIG. 9;

FIG. 11 is a diagram of an interleaver of FIG. 10;

FIGS. 12A and 12B are diagrams of a trellis encoder of FIG. 10;

FIG. 13 is a diagram of a field sync generator of FIG. 10;

FIG. 14 is a diagram of a signal detector of the common broadcast receiver according to an exemplary embodiment of the present invention;

FIGS. 15A and 15B are detailed diagrams of the signal detector of FIG. 14;

FIG. 16 is a diagram of a signal detector of the common broadcast receiver according to another exemplary embodiment of the present invention;

FIGS. 17A and 17B are diagrams of constellations of a signal output from an equalizer;

FIGS. 18A and 18B are detailed diagrams of the signal detector of FIG. 16;

FIG. 19 is a flowchart of a received signal processing method of the common broadcast receiver according to an exemplary embodiment of the present invention;

FIG. 20 is a detailed flowchart of the received signal processing method of the common broadcast receiver of FIGS. 19; and

FIG. 21 is a further detailed flowchart of the received signal processing method of the common broadcast receiver of FIG. 19.

### DETAILED DESCRIPTION OF THE EXEMPLARY EMBODIMENTS

Certain exemplary embodiments of the present invention will now be described in greater detail with reference to the accompanying drawings.

In the following description, the same drawing reference numerals are used for the same elements even in different drawings. The matters defined in the description, such as detailed construction and elements, are provided to assist in a comprehensive understanding of the invention. Thus, it is apparent that the exemplary embodiments of the present invention can be carried out without those specifically defined matters. Also, well-known functions or constructions are not described in detail since they would obscure the invention with unnecessary detail.

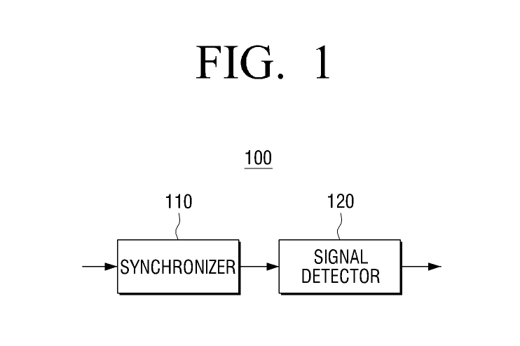

FIG. 1 depicts a common broadcast receiver according to an exemplary embodiment of the present invention. Referring to FIG. 1, the common broadcast receiver 100 for receiving and processing a plurality of broadcast signals, includes a synchronizer 110 and a signal detector 120.

The synchronizer 110 receives any one of a cable broadcast signal, a terrestrial broadcast signal, and a mobile broadcast signal including a training signal generated by a Deterministic Trellis Reset (DTR) and inserted in a data region, and synchronizes the received broadcast signal.

The signal detector 120 detects any one of the cable broadcast signal, the terrestrial broadcast signal, and the mobile broadcast signal from the synchronized broadcast signal.

Although it is not illustrated in FIG. 1, it is advantageous that the signal recovery after the signal detection at the signal detector 120 is performed using an MPEG-2 video codec. Yet, the signal recovery may make use of various video codecs such as MPEG-4 and H.263.

Although it is not illustrated in FIG. 1, the synchronizer 110 may include a tuner (not shown) for tuning to a channel of the signal received via an antenna (not shown). It should be appreciated that the synchronizer 110 can carry out demodulation; that is, Carrier Recovery (CR) for the frequency synchronization and Symbol Timing Recovery (STR) for the symbol timing synchronization.

The common broadcast receiver 100 can be implemented in the form of a single chip, equipped to a hand phone, a navigator, an MP3 player, a PMP, and so on, and embedded to the broadcast receiver of a desktop computer, TV, or a set-top box.

Prior to the descriptions on the common broadcast receiver 100 according to an exemplary embodiment of the present invention, the cable broadcast signal, the terrestrial broadcast signal, the mobile broadcast signal transmitted from the transmitting side to the common broadcast receiver 100 are explained in detail.

A structure of a transmitter for transmitting the cable broadcast signal from the transmitting side and a structure of a transmitter for transmitting the terrestrial broadcast signal from the transmitting side, which are well known to one skilled in the art, shall be omitted here. A structure of a transmitter for transmitting the mobile broadcast signal from the transmitting side and the mobile broadcast signal including the inserted training signal generated by the DTR are now elucidated by referring to the drawings.

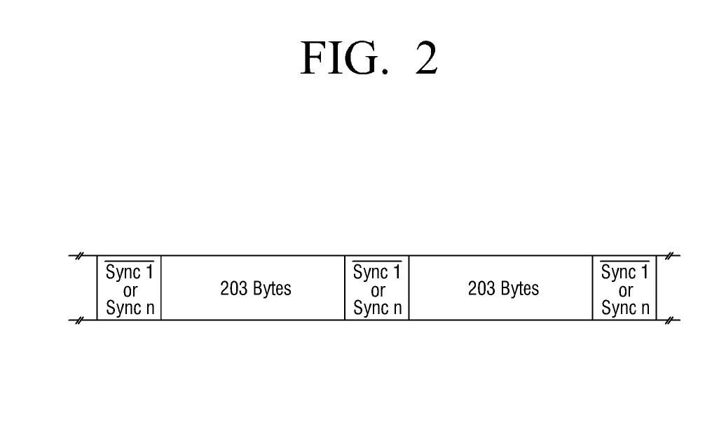

FIG. 2 depicts an example of the cable broadcast signal. Herein, preferably, the cable broadcast signal conforms to the ITU-T J. 83 standard. The cable broadcast signal periodically repeats a 1-byte sync signal and a 203-byte data signal. The 1-byte sync signal can be either Sync 1 or Sync n according to a preset scheme. The 203-byte data signal can be modulated using a Quadrature Amplitude Modulation (QAM) scheme at the transmitting side and transmitted to the receiving side.

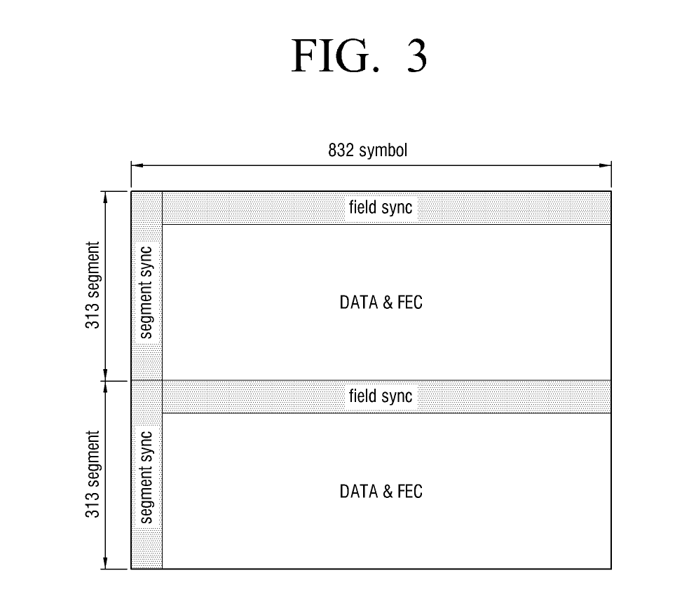

FIG. 3 depicts an example of the terrestrial broadcast signal. Preferably, the terrestrial broadcast signal conforms to the ATSC A. 53 (8-VSB) standard. In the terrestrial broadcast signal, one frame includes 2 fields. One field includes one field sync region which is a first segment; that is, a field sync segment, and 312 data regions; that is, data segments. Namely, the frame can be constituted by adding one field sync packet to the packet group including 312 packets. One segment; that is, one packet is 832 symbols in total including a 4-symbol segment sync signal and 828 data symbols.

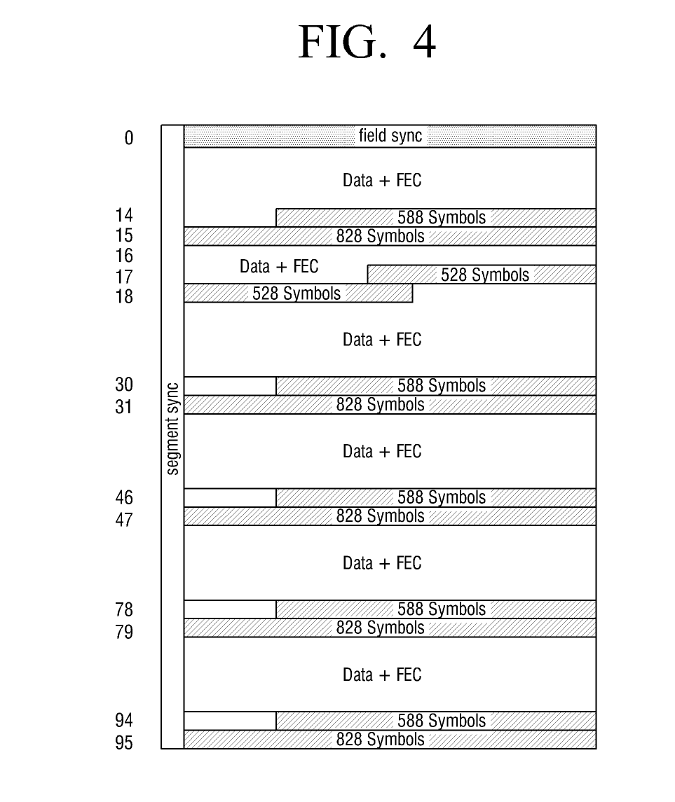

FIG. 4 depicts an example of the mobile broadcast signal. Preferably, the mobile broadcast signal conforms to the ATSC-M/H standard. The mobile broadcast signal of FIG. 4 differs from the terrestrial broadcast signal of FIG. 3 in that the training signal is inserted to the data region. More specifically, in FIG. 4, six training signals, including five training signals that are the same and one training signal that is different from the five training signals, are inserted to the data region. When one segment is 832 symbols in size as shown in FIG. 4, the size of the training signal can be greater than 832 symbols (e.g., 1416 symbols or 1056 symbols) and can be stuffed over two segments.

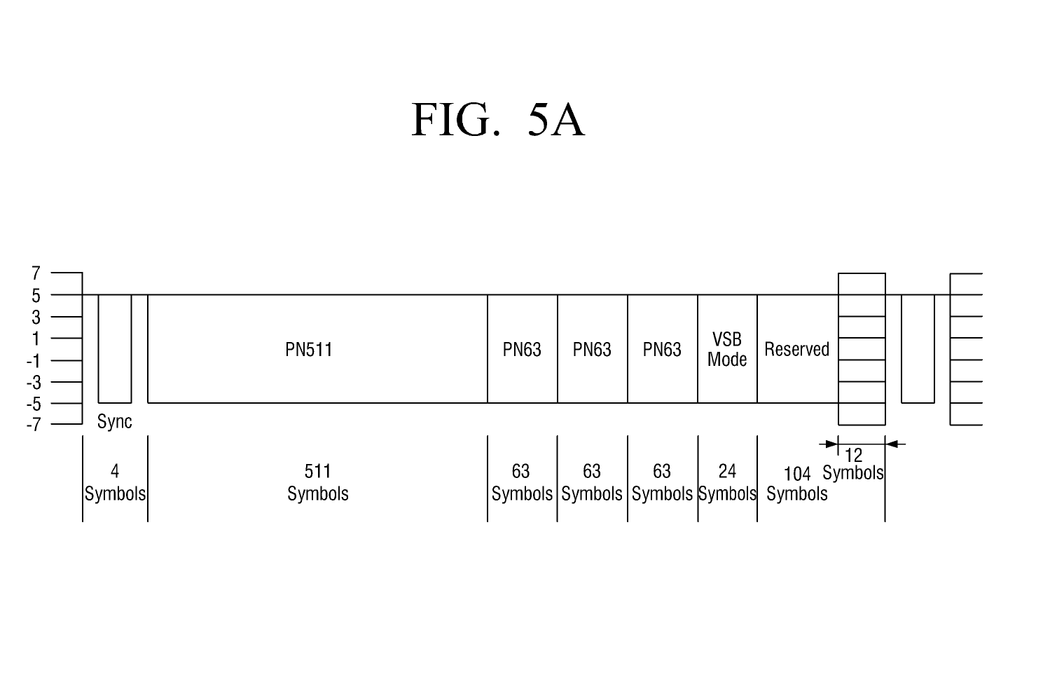

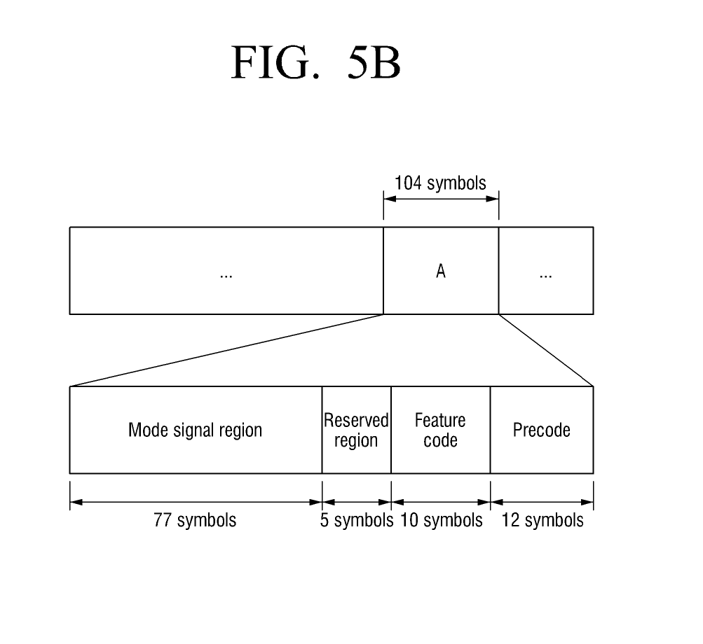

FIGS. 5A and 5B depict the field sync region of the terrestrial broadcast signal and the mobile broadcast signal. Referring first to FIG. 5A, the field sync signal includes a 4-symbol segment sync, a 511-symbol Pseudo Nose (PN) sequence, three 63-symbol PN sequences, a 24-symbol VSB mode, and a 104-symbol reserved region.

In the 104 symbols of the reserved region of FIG. 5B, the last 12 symbols can be used as a precode region and 10 symbols before the precode region can be used as a feature code region. Herein, the feature code (i.e., a company code) can record a code indicative of the feature such as additional data version, provider company, and improvement classification. The 104-symbol reversed region can include a 5-symbol reserved region and a 77-symbol mode signal region.

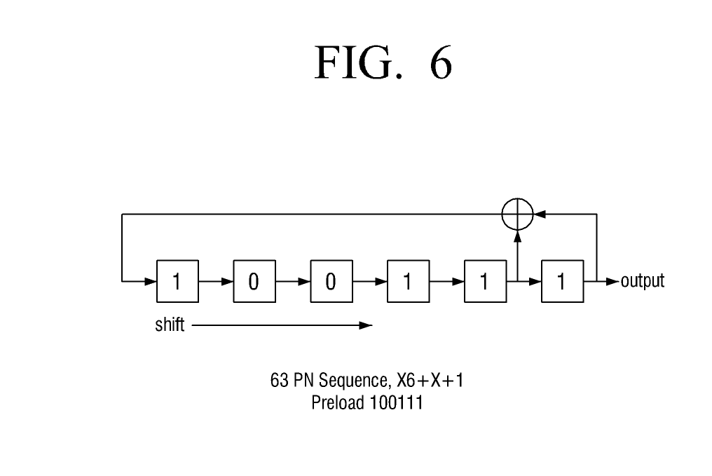

FIG. 6 depicts an example of a 63 sequence generator. The field sync signal region of the terrestrial broadcast signal and the mobile broadcast signal can include 63 PN sequences as in FIG. 5A. The 63 PN sequences can be generated by a PN sequence generator including 6 registers as shown in FIG. 6.

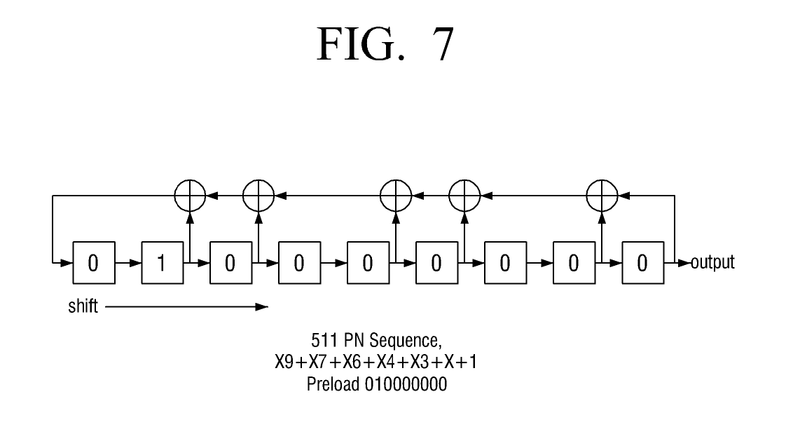

FIG. 7 depicts an example of a 511 PN sequence generator. The 511 PN sequences in the field sync region of the terrestrial broadcast signal and the mobile broadcast signal can be generated by a PN sequence generator of FIG. 7, which includes 9 registers.

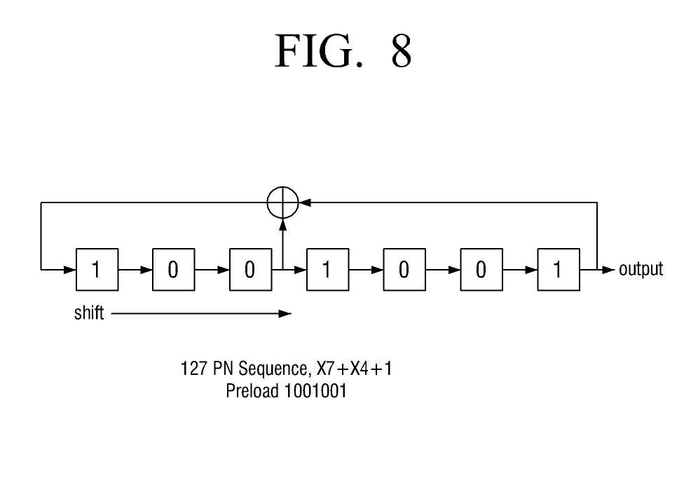

FIG. 8 depicts an example of a 127 PN sequence generator. Referring back to FIGS. 5A and 5B, the mobile broadcast signal can fill 82 symbols of 92 symbols excluding 12 symbols (the precode) of 104 symbols of the reserved region, using the 127 PN sequence generator. Accordingly, the mobile broadcast signal can be constituted using the 127 PN sequence generator.

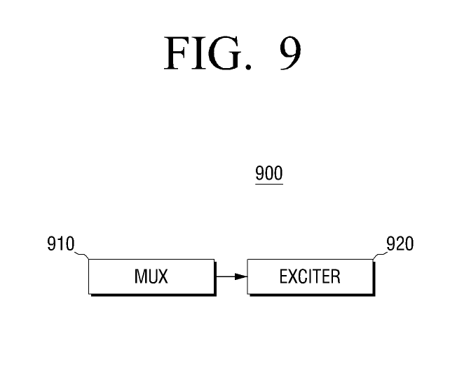

FIG. 9 depicts an example of the transmitter of the transmitting side for sending the mobile broadcast signal from the transmitting side. The transmitter 900 of FIG. 9 includes a MUX 910 and an exciter 920.

The MUX 910 generates a transport stream including a normal data stream and an additional data stream. The normal data stream represents a data stream transmitted for the broadcast in a conventional digital broadcasting system. The additional data stream represents a stream robust to error, which can be processed at a mobile device, and processed by applying a coding rate using a coding scheme different from the normal data stream. Ultimately, the terrestrial broadcast signal does not include the additional data stream, whereas the mobile broadcast signal can include the additional data stream in addition to the normal data stream.

The MUX 910 can generate the transport stream by properly formatting and inserting the additional data stream to the normal data stream.

In more detail, the MUX 910 can sequentially insert one or more additional data streams over the normal data stream units in a preset pattern in an alternating manner. Herein, the stream unit indicates the unit defined to distinguish the normal data and can be a segment unit or a packet unit.

The exciter 920 processes the transport stream generated at the MUX 910 and transmits the processed transport stream in the channel. The exciter 920 performs trellis encoding on the transport stream, resets memories used for the trellis encoding at a certain time point, and inserts the training signal, which is known between the transmitter and the receiver, to the transport stream. That is, the exciter 920 can carry out the DTR which resets the memories used for the trellis encoding at a certain time point. It is noted that the DTR is performed only on the mobile broadcast signal.

Herein, the training signal is inserted to the data region of the transport stream and can be generated in the size greater than the field sync signal. As shown in FIG. 4, the training signal is 1424 or 1056 symbols in size and can be inserted over two segments.

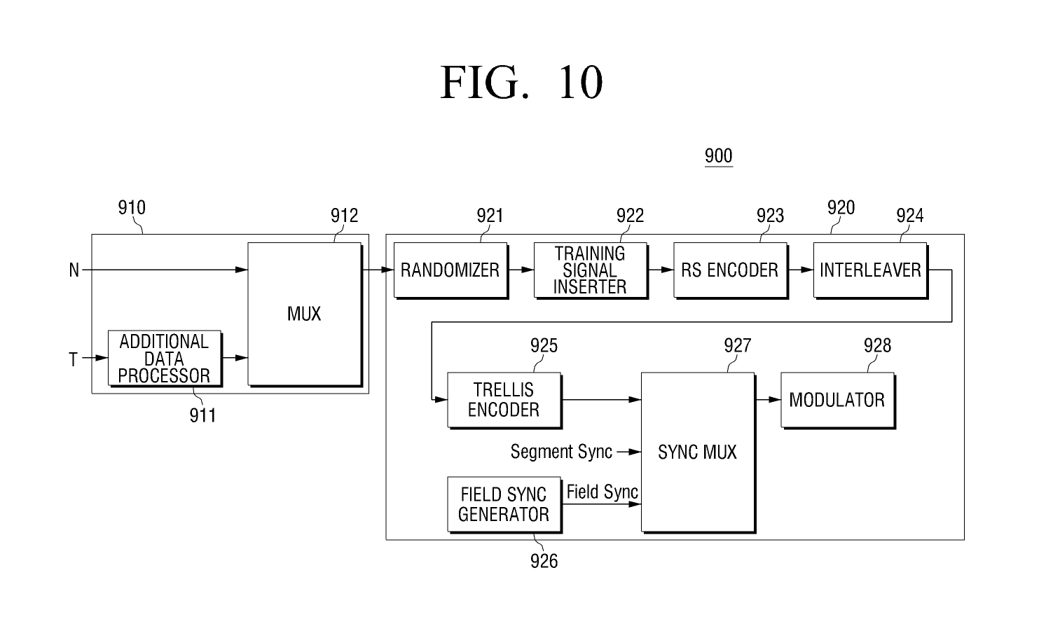

FIG. 10 is a detailed diagram of the digital broadcast transmitter of FIG. 9. An additional data processor 911, which processes the additional data stream T, receives one or more data streams to be additionally transmitted by inserting them into the normal data stream N, from an internal or external source, processes the data streams to make them robust to error, and provides the processed data streams to a MUX 912.

The MUX 912 generates the transport stream by inserting the one or more additional data streams T output from the additional data processor 911 to the normal data stream N.

The additional data processor 911 can include a single preprocessor or a plurality of preprocessors (not shown) according to the number of the additional data. The preprocessor (not shown) can include an RS-encoder (not shown), an interleaver (not shown), and a packet formatter (not shown). Through the RS encoding, the interleaving, and the packet formatting, the additional data streams can be made to be robust to errors.

The additional data stream input to the preprocessor (not shown) is encoded at the RS-encoder (not shown) and interleaved by the interleaver (not shown). The packet formatter (not shown) packet-formats the additional data stream output from the interleaver.

A randomizer 921 randomizes the generated transport stream.

A training signal inserter 922 inserts the training signal, which is known to the receiving side, into the transport stream. The inserted training signal can be used by the receiving side to determine whether or not the received transport stream contains the additional data stream. Also, the inserted training signal can be used for the demodulation or the equalization of the receiving side to thus enhance the reception performance. Herein, the training signal is in the size greater than the field sync signal and can be inserted over two segments. Accordingly, the training signal can be a long training symbol.

An RS encoder 923 encodes the transport stream including the inserted training signal. An interleaver 924 interleaves the encoded transport stream and provides the interleaved transport stream to a trellis encoder 925.

The trellis encoder 925 trellis-encodes the interleaved transport stream and outputs the trellis-encoded transport stream to a sync MUX 927.

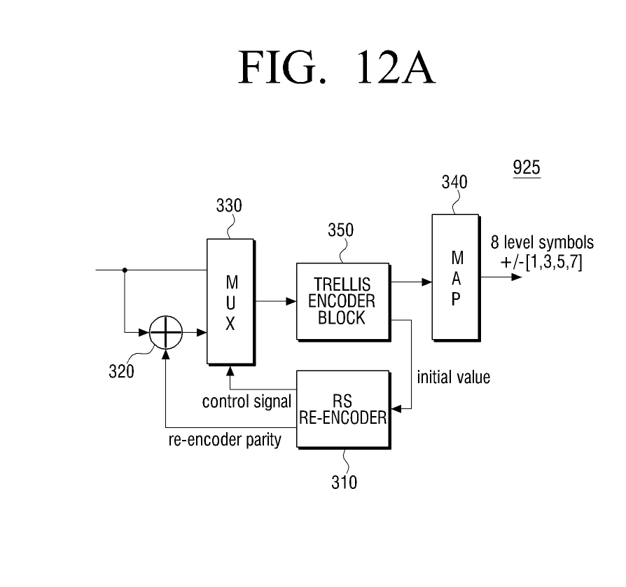

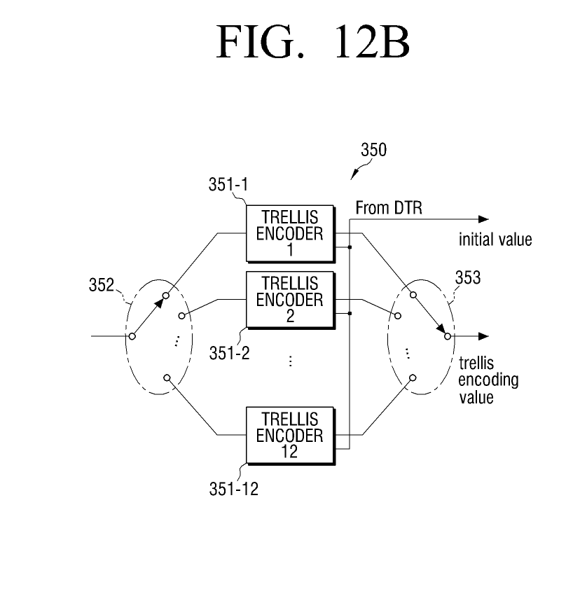

The trellis encoder 925 can perform the trellis resetting at a proper time according to the insertion of the training signal. In further detail, the trellis encoder 925 can employ a plurality of internal memories (e.g., 3 shift registers) in the trellis encoding. When the trellis encoding is conducted on the training signal, known data values can be modified by values pre-stored to the internal memories. To avoid this, prior to the processing of the training signal, it is advantageous to perform the trellis resetting which resets the interval memories to their initial values. When the trellis resetting is carried out, parity correction may be conducted to avoid incorrectness of the parity in accordance with the trellis resetting. In this case, an RS re-encoder (not shown) can be further provided, which shall be described in more detail by referring to FIGS. 12A and 12B.

A field sync generator 926 generates the field sync signal to be inserted to the transport stream.

According to the field sync signal generated at the field sync generator 926, the mobile broadcast signal can be generated in the form different from the cable broadcast signal and the terrestrial broadcast signal.

The sync MUX 927 inserts the field sync signal generated at the field sync generator 926 and the segment sync signal into the trellis-encoded transport stream.

A modulator 928 modulates the transport stream processed at the sync MUX 927 and transmits the modulated transport stream over the channel. More specifically, the modulator 928 can convert the transport stream to an RF channel signal through VSB modulation, RF modulation, and so forth.

In various exemplary embodiments, other various components than the components of FIG. 10 can be further provided. For example, a pilot inserter (not shown) can insert a pilot by adding a certain DC value, a pre-equalizer (not shown) can equalize the dual transport stream including the inserted pilot to minimize inter-symbol interference, and a postprocessor (not shown) can post-process the interleaved transport stream.

In various embodiments, some of the components of FIG. 10 can be deleted or their arrangement can be altered. For instance, the randomizer 921 can be omitted if necessary.

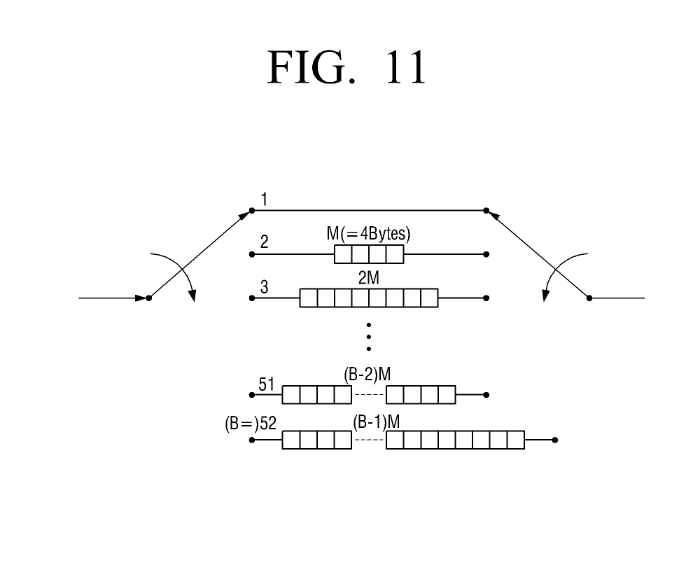

FIG. 11 depicts the interleaver of FIG. 10. The interleaver 924 of FIG. 11 can be implemented as a convolutional byte interleaver. When one field includes 312 segments, the interleaver 924 can operate by 53 data segments.

Referring to FIG. 11, the transport stream output from the RS encoder 923 is divided on the byte basis, sequentially stored to the multiple shift registers, and then output to the trellis encoder 925 in order. Thus, the bytewise interleaving can be accomplished.

FIGS. 12A and 12B depict the trellis encoder of FIG. 10.

The trellis encoder 925 of FIG. 12A includes a Reed-Solomon (RS) re-encoder 310, an adder 320, a MUX 330, a MAP 340, and a trellis encoder block 350.

The MUX 330 can function in one of an operation mode for trellis-encoding each packet of the input transport stream (hereinafter, referred to as a normal mode), and an operation mode for trellis-encoding the packets added by the adder 320 (hereafter, referred to as a parity correction mode). The operation mode of the MUX 330 is determined by a control signal received from the RS re-encoder 310.

In the normal mode, the MUX 330 forwards the input transport stream to the trellis encoder block 350. By contrast, in the parity correction mode, the MUX 330 forwards the stream output from the adder 320 to the trellis encoder block 350.

The trellis encoder block 350 trellis-encodes the packets received from the MUX 330. The trellis encoder block 350 can trellis-encode the packets according to the external control signal. Advantageously, the above-stated training signal is initialized right before the trellis encoding. To prevent the training signal from being distorted by the pre-stored value of its memory, the trellis encoder block 350 initializes the training signal before the trellis encoding by locating the insertion position of the training signal.

The RS re-encoder 310 re-generates the parity corresponding to the changed packet using the initial value calculated in the initialization of the trellis encoder block 350.

The adder 320 adds the parity re-generated by the RS re-encoder 310 and the packet fed from the outside and provides the added packets to the MUX 330. Herein, the addition is conducted as follows.

A. omitted . . . 101001010111001010101011AAAAA . . . omitted

B. omitted . . . 000000000000010000000000BBBBB . . . omitted

C. omitted . . . 101001010111011010101011CCCCC . . . omitted

A) shows the packet input from the outside, B) shows the RS-re-encoded packet, and C) shows the result of the Exclusive OR of A) and B) using the adder 320. When the underlined part in the packet A) is input to the trellis encoder block 350, the initialization is performed. In this case, the value corresponding to the value pre-stored to the trellis encoder block 350 is provided to the RS re-encoder 310 and the RS re-encoder 310 adds the parity to the input value and outputs the packet B). The underlined part in the packet B) indicates the modified value corresponding to the underlined part of the packet A). The parity corresponding to the underlined part of the packet B) is BBBB, which is regenerated.

The adder 320 outputs the packet C) by applying the exclusive OR to the packet A) and the packet B). In the packet C), the underlined part in the initially input packet A) is modified to “01” and the parity is changed from AAAAA to CCCCC.

The MUX 330 enters the normal operation mode when the initialization and the parity correction are completed, and provides the dual transport stream to the trellis encoder block 350.

The MAP 340 symbol-maps the trellis-encoded packets to 8 levels. The MAP 340 can carry out the mapping as shown in Table 1.

TABLE 1

| Z2 | Z1 | Z0 | R |
|---|---|---|---|
| 0 | 0 | 0 | −7 |
| 0 | 0 | 1 | −5 |
| 0 | 1 | 0 | −3 |
| 0 | 1 | 1 | −1 |
| 1 | 0 | 0 | +1 |
| 1 | 0 | 1 | +3 |
| 1 | 1 | 0 | +5 |
| 1 | 1 | 1 | +7 |

In Table 1, Z0, Z1 and Z2 denotes the trellis encoding value output from the trellis encoder block 350, and R denotes the corresponding mapping output value. For example, when the trellis encoding value of 0, 0, 0 is output, the MAP 340 outputs −7.

FIG. 12B depicts the trellis encoder block 350 applied to the trellis encoder 925 of FIG. 10. The trellis encoder block 350 of FIG. 12B includes a plurality of trellis encoders 351-1 through 351-12, a splitter 352, and an encoding output part 353.

The splitter 352 outputs the stream output from the MUX 330 to the trellis encoders 351-1 through 351-12 in sequence. In so doing, the splitter 352 can output the stream on a byte basis.

The trellis encoders 351-1 through 351-12 each trellis-encode the input stream. The trellis encoder 1 through the trellis encoder 12 are selected in succession to output the trellis encoding value. Meanwhile, in the initialization period, the trellis encoders 351-1 through 351-12 provide the value pre-stored to their interval memories (not shown) to the RS re-encoder 310 as the initial value. The RS re-encoder 310 corrects the parity by adding the parity to the fed initial value and outputting to the adder 320.

The encoding output part 353 sequentially detects the encoding values output from the trellis encoders 351-1 through 351-12 and outputs the detected encoding values to the MAP 340.

The trellis encoders 351-1 through 351-12 each include a plurality of memories for the trellis encoding. Just prior to the trellis encoding, the region where a supplementary reference signal is inserted is initialized. Each individual memory is reset according to the initialization. In so doing, the value pre-stored to the memory is provided to the RS re-encoder 310 as the initial value.

In further detail, each trellis encoder can include three memories; that is, a first memory, a second memory, and a third memory. As the initialization proceeds, the first memory outputs the previously stored value (hereafter, referred to as a first initial value) as the initial value. The third memory shifts the previously stored value, to the second memory concurrently with the initialization. According to the shift operation, the value pre-stored to the second memory (hereafter, referred to as a second initial value) is output as the initial value. The RS re-encoder 310 combines the first and second initial values and utilizes the combined value as the initial value.

Since the second and third memories, which are arranged side by side, execute the shift operation, two control signal symbols are required to initialize all of the second memory and the third memory. There are 8 cases (000, 111, 001, 010, 100, 110, 101 and 011) of the initial value condition produced using all of the three memories. X0 and X1 values denoting the first and second initial values are fed to the RS re-encoder 310, to thus modify the parity.

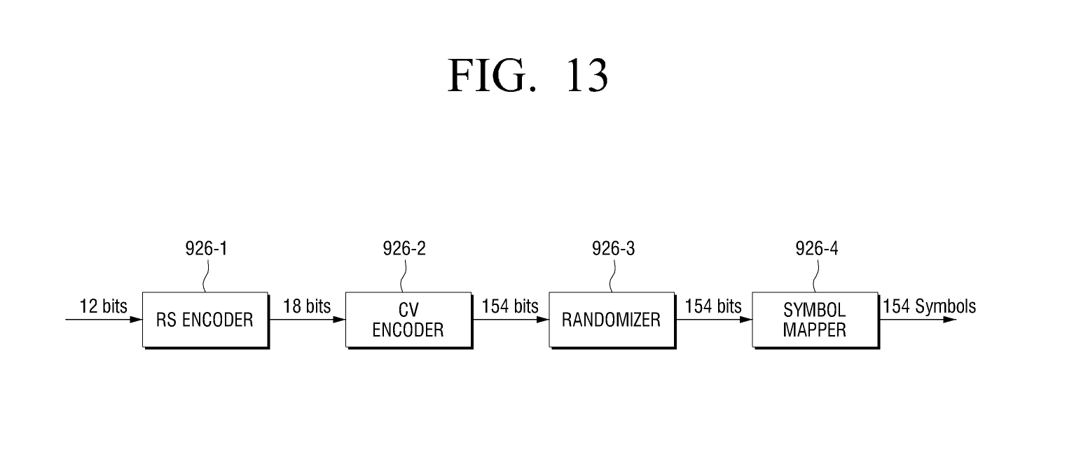

FIG. 13 depicts the field sync generator of FIG. 10. In FIG. 13, the RS parity is added to 12-bit mode information at an RS encoder 926-1. When the RS (6. 4) encoder of GF (8) is employed, the information becomes 18 bits after the RS encoding. Next, a CV encoder 926-2 performs the convolutional encoding. When 1/7 rate tail byte convolutional coding is applied, the information finally becomes 154 bits. That is, when 4 tail bits are added to the 18-bit mode information and the 1/7 convolutional coding is applied, 154 bits are produced. The convolutional encoding mode information is converted to 154 symbols through the randomizer 926-3 and the symbol mapper 926-4, which is merely an example. Note that part of the components can be deleted or added in various embodiments of the present invention, and that the arrangement order of the components can be altered.

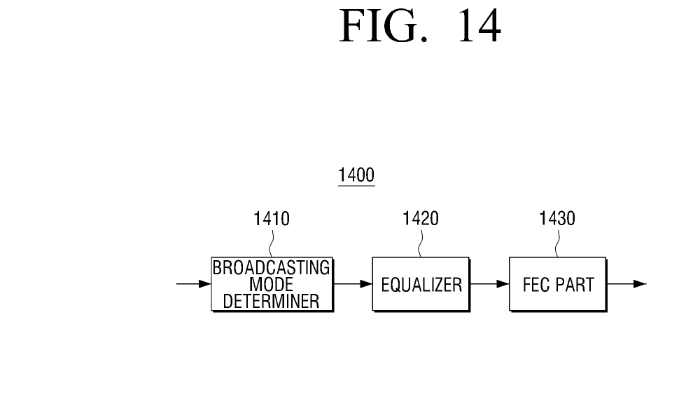

FIG. 14 depicts a signal detector of the common broadcast receiver according to an exemplary embodiment of the present invention. The signal detector 1400 of FIG. 14 can include a broadcasting mode determiner 1410, an equalizer 1420, and a Forward Error Correction (FEC) part 1430.

The broadcasting mode determiner 1410 determines whether the synchronized broadcast signal is the cable broadcast signal, the terrestrial broadcast signal, or the mobile broadcast signal. The equalizer 1420 equalizes the synchronized broadcast signal according to the determined broadcasting mode. The FEC part 1430 corrects errors in the equalized signal.

Herein, when the broadcast signal determined at the broadcasting mode determiner 1410 is the cable broadcast signal, the equalizer 1420 equalizes the broadcast signal according to the cable broadcasting mode and the FEC part 1430 corrects errors according to the cable broadcast signal. In more detail, according to the broadcasting mode corresponding to the broadcast signal, the equalizer 1420 and the FEC part 1430 can perform the equalization and the error correction respectively. In so doing, the equalizer 1420 and the FEC part 1430 can include a plurality of equalizers (not shown) and a plurality of FEC parts (not shown) corresponding to the respective broadcast signals.

Typically, the equalizer 1420 and the FEC part 1430 have different structures depending on the broadcast signal as mentioned above. Since the substantial function of the equalizer 1420 and the FEC part 1430 is practically similar, a common equalizer (not shown) and a common FEC part (not shown) may be provided.

The broadcasting mode determiner 1410 can determine one of the received broadcast signals in various manners. For example, the broadcasting mode determiner 1410 can determine whether the received broadcast signal is the cable broadcast signal and then determine whether the received broadcast signal is either the terrestrial broadcast signal or the mobile broadcast signal.

When the 1-byte sync signal is detected from the synchronized broadcast signal repeatedly in a preset cycle, the broadcasting mode determiner 1410 can determine the synchronized broadcast signal as the cable broadcast signal. Referring back to FIG. 2, the cable broadcast signal periodically includes the 1-byte sync signal in every 204 bytes. Naturally, when the 1-byte sync signal is detected regardless of Sync 1 and Sync n, the cable broadcast signal can be identified. The broadcasting mode determiner 1410 can compare the synchronized signal received from the transmitting side and the signal already known to the receiving side using their correlation, and determine whether there exists the 1-byte sync signal depending on the detection of a peak value. It should be understood that the 1-byte sync signal can be detected using a well-known sliding sum method.

When not detecting the field sync signal region from the synchronized broadcast signal, the broadcasting mode determiner 1410 can determine the synchronized broadcast signal as the cable broadcast signal. Herein, upon detecting any one of the PN sequence in the predefined form, the VSB mode, and the reserved region in the synchronized broadcast signal, the broadcasting mode determiner 1410 determines the detection of the field sync signal region. More specifically, since the cable broadcast signal does not include the field sync signal region as shown in FIGS. 2, 3 and 4, the cable broadcast signal can be identified depending on the presence or the absence of the field sync signal region. Because the field sync signal, which is preset signal, is already known to the receiving side, the broadcasting mode determiner 1410 can identify the cable broadcast signal using the correlation. Notably, this method cannot distinguish the terrestrial broadcast signal and the mobile broadcast signal.

When the training signal is inserted in the data region of the synchronized broadcast signal, the broadcasting mode determiner 1410 can determine the synchronized broadcast signal as the mobile broadcast signal. Referring back to FIGS. 3 and 4, the data region of the terrestrial broadcast signal does not include the inserted training signal, whereas the data region of the mobile broadcast signal includes the inserted training signal. Consequently, upon detecting the training signal in the data region of the synchronized broadcast signal, the broadcasting mode determiner 1410 determines that the synchronized broadcast signal is a mobile broadcast signal. Otherwise, the broadcasting mode determiner 1410 determines that the synchronized broadcast signal is a terrestrial broadcast signal.

As the receiving side can locate the field sync signal region as stated above, the location of the training symbol can be acquired based on the location of the field sync signal. Referring back to FIG. 4, the training signal can be detected after the 15th segment and the 16th segment from the field sync located at the 0th segment, and the training signal can be detected at the 17th segment and the 18th segment. As such, by acquiring the rule of the arrangement of the training signal, the training signal inserted to the data region of the synchronized broadcast signal can be detected.

Alternatively, based on the feature code value in the field sync signal region of the synchronized broadcast signal, the broadcasting mode determiner 1410 can determine which one of the terrestrial broadcast signal and the mobile broadcast signal is the synchronized broadcast signal. Referring back to FIG. 5B, the feature code value can be the company code value. For example, when the company code value is “1”, the broadcasting mode determiner 1410 can determine that the synchronized broadcast signal is the mobile broadcast signal. When the company code value is “0”, the broadcasting mode determiner 1410 can determine that the synchronized broadcast signal is the terrestrial broadcast signal.

Alternatively, when the PN sequence of the preset size exists in the reserved region of the field sync signal region of the synchronized broadcast signal, the broadcasting mode determiner 1410 can determine the synchronized broadcast signal as the mobile broadcast signal. Referring back to FIG. 5B, when the PN sequence is inserted with respect to the 82 symbols except for the 10-symbol feature code and the 12-symbol precode in the 104-symbol reserved region, the broadcasting mode determiner 1410 can determine that the synchronized broadcast signal is the mobile broadcast signal. Otherwise, the broadcasting mode determiner 1410 can determine that the synchronized broadcast signal is the terrestrial broadcast signal. As for the mobile broadcast signal, the PN sequence generator of FIG. 8 can generate 82 symbols out of the 127 symbols.

Alternatively, when the FEC coding is performed on the symbols of the preset size in the reserved region of the field sync signal region of the synchronized broadcast signal, the broadcasting mode determiner 1410 can determine that the synchronized broadcast signal is the mobile broadcast signal. Referring back to FIG. 5B, when the FEC coding is applied to the 77-symbol mode signal region of the field sync signal region, the broadcasting mode determiner 1410 can determine that the synchronized broadcast signal is the mobile broadcast signal. Otherwise, the broadcasting mode determiner 1410 can determine that the synchronized broadcast signal is the terrestrial broadcast signal.

Alternatively, the broadcasting mode determiner 1410 assumes that the synchronized broadcast signal is either the terrestrial broadcast signal or the mobile broadcast signal. Next, when the error-corrected signal output from the FEC part 1430 is the normal signal, the error-corrected signal is output. When the error-corrected signal is an error signal, the assumption is modified, the equalizer 1420 performs the equalization, and the FEC part 1430 sequentially performs the error correction. Thus, the broadcasting mode determiner 1410 can determine whether the synchronized broadcast signal is either the terrestrial broadcast signal or the mobile broadcast signal.

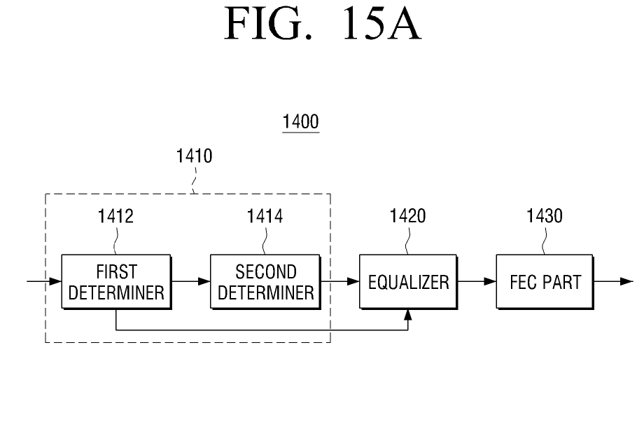

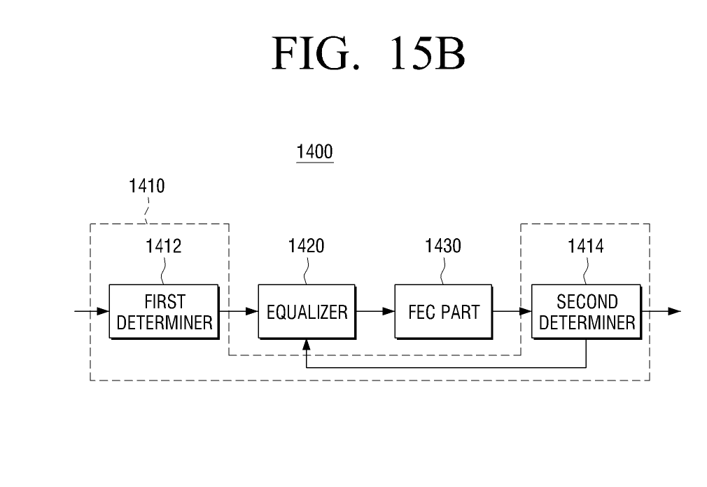

FIGS. 15A and 15B are detailed diagrams of the signal detector of FIG. 14. To ease the understanding of FIGS. 15A and 15B, the broadcasting mode determiner 1410 includes a first determiner 1412 for determining whether the input signal is the cable broadcast signal, and a second determiner 1414 for determining whether the input signal is the terrestrial broadcast signal or the mobile broadcast signal. It should be appreciated that the broadcasting mode determiner 1410 can be constituted as the single unit as shown in FIG. 14 or as the separate units as shown in FIGS. 15A and 15B.

In FIG. 15A, when the signal input to the broadcasting mode determiner 1410 is the cable broadcast signal, the first determiner 1412 can determine the input signal as the cable broadcast signal using one of the aforementioned methods (whether the 1-byte sync signal is included and whether there exists the field sync signal region). In so doing, there is no need to use the second determiner 1414. Hence, the equalizer 1420 can conduct the equalization and the FEC part 1430 can conduct the error correction according to a control signal of a controller (not shown).

When the signal input to the broadcasting mode determiner 1410 is the terrestrial broadcast signal, the first determiner 1412 can identify that the input signal is not the cable broadcast signal and the second determiner 1414 can determine the signal input to the broadcasting mode determiner 1410 as the terrestrial broadcast signal using the above-stated methods. Next, the signal output from the second determiner 1414 can pass through the equalization at the equalizer 1420 and the error correction at the FEC part 1430. When the signal input the broadcasting mode determiner 1410 is the terrestrial broadcast signal, the operations are the same as for the terrestrial broadcast signal.

In FIG. 15B, the second determiner 1414 of the broadcasting mode determiner 1410 is positioned after the FEC part 1430. When the signal input to the first determiner 1412 is the cable broadcast signal, the signal output from the first determiner 1412 goes through the equalization at the equalizer 1420 and the error correction at the FEC part 1430.

By contrast, when the input signal to the first determiner 1412 is the terrestrial broadcast signal, it is advantageous that the second determiner 1414 follows the first determiner 1412 as shown in FIG. 15A and determines whether the signal output from the first determiner 1412 is the terrestrial broadcast signal or the mobile broadcast signal. Yet, the second determiner 1414 may follow the FEC part 1430 and determine whether the signal output from the FEC part 1430 is the terrestrial broadcast signal or the mobile broadcast signal depending on whether the FEC coding is applied to the 77 symbols in the reserved region of the field sync signal region of the signal output from the FEC part 1430. Alternatively, depending on whether the FEC part 1430 outputs the normal signal or the error signal, the second determiner 1414 may determine whether the signal output from the FEC part 1430 is the terrestrial broadcast signal or the mobile broadcast signal as stated earlier. In this situation, when the second determiner 1414 determines either the terrestrial broadcast signal or the mobile broadcast signal, the broadcast signal can be fed back to the equalizer 1420 to pass through the equalization and then the error correction at the FEC part 1430.

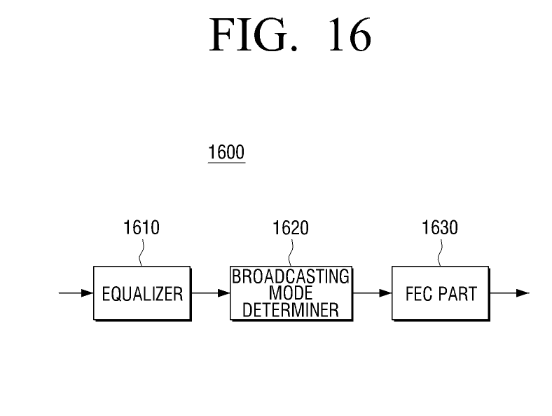

FIG. 16 depicts the signal detector of the common broadcast receiver according to another exemplary embodiment of the present invention. The signal detector 1600 of FIG. 16 can include an equalizer 1610, a broadcasting mode determiner 1620, and an FEC part 1630. Contrary to FIG. 14, the broadcasting mode determiner 1620 can follow the equalizer 1610.

The broadcasting mode determiner 1620 can determine whether the equalized broadcast signal is the cable broadcast signal or not, according to the constellation of the equalized broadcast signal.

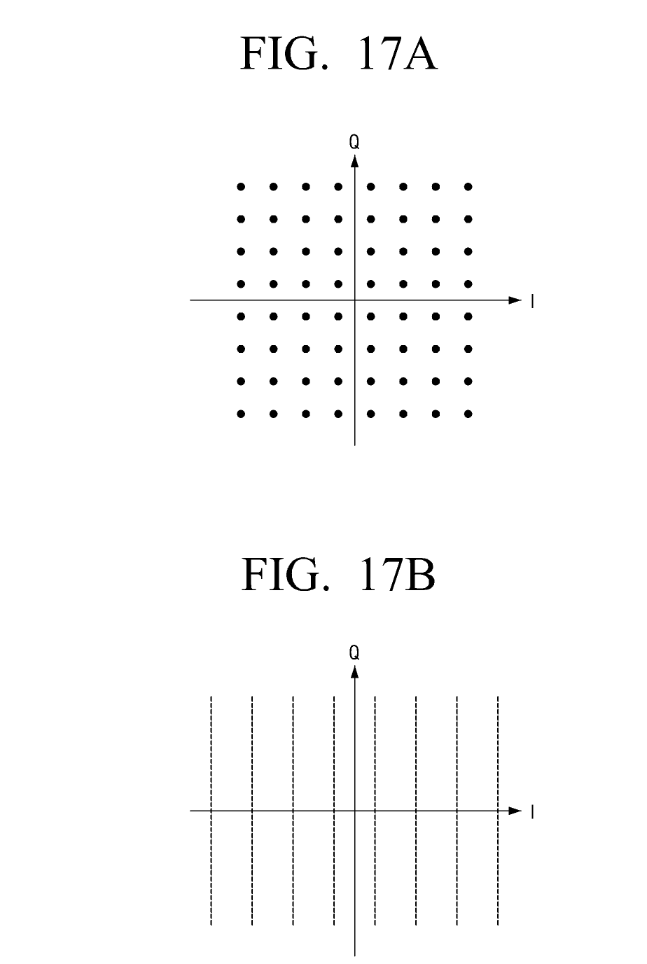

FIGS. 17A and 17B depict the constellation of the signal output from the equalizer. When the signal output from the equalizer 1610 is the cable broadcast signal (e.g., 64 QAM signal), the constellation of FIG. 17A is produced. When the signal output from the equalizer 1610 is either the terrestrial broadcast signal or the mobile broadcast signal, the signal output from the equalizer 1610 produces the constellation of FIG. 17B according to the 8-VSB scheme. Correspondingly, based on the constellation of the equalized broadcast signal, the broadcasting mode determiner 1620 can determine whether the equalized broadcast signal is the cable broadcast signal or not. Notably, when the cable broadcast signal output from the equalizer 1610 is not the 64 QAM signal, the distinction of the cable broadcast signal and the terrestrial broadcast signal or the distinction of the cable broadcast signal and the mobile broadcast signal can be facilitated.

In FIG. 16, it is preferable to determine whether the equalized broadcast signal is the cable broadcast signal or not based on the constellation of the equalized broadcast signal. By contrast, whether the equalized broadcast signal is the cable broadcast signal can be determined depending on whether the equalized broadcast signal includes the 1-byte sync signal or whether the field sync signal region is detected from the equalized broadcast signal. In addition, it is noted that whether the equalized broadcast signal is the terrestrial broadcast signal or the mobile broadcast signal can be determined after or before the FEC part 1630 as described in FIGS. 15A and 15B.

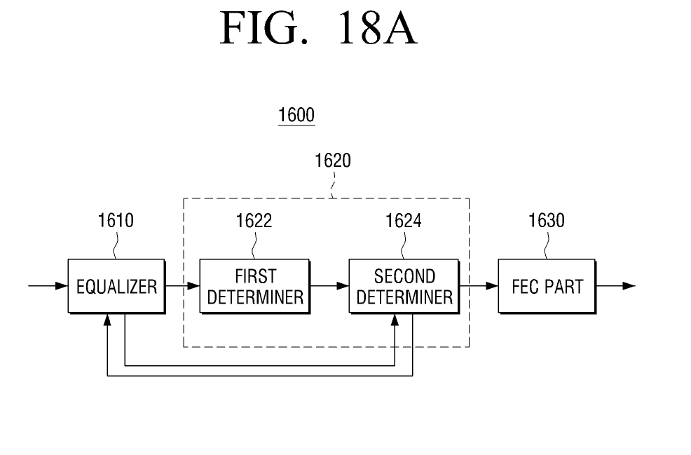

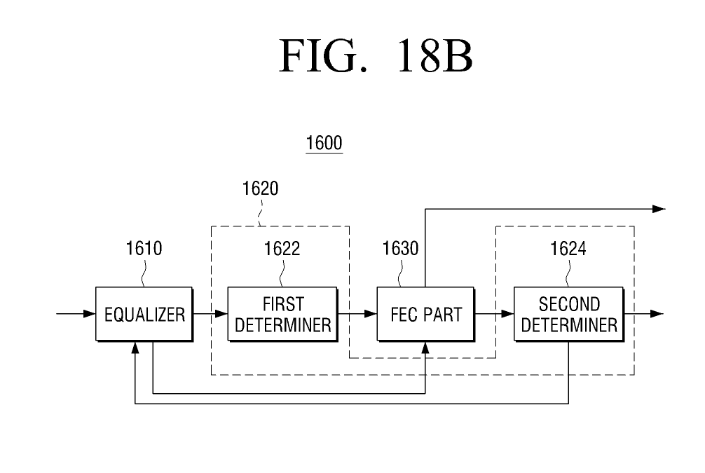

FIGS. 18A and 18B depict the detailed operations of the signal detector of FIG. 16.

Similar to FIG. 17, the first determiner 1622 of FIGS. 18A and 18B can determine whether the broadcast signal is the cable broadcast signal or not, according to the constellation of the signal output from the equalizer 1610. Hence, after assuming that the input signal of the equalizer 1610 is a particular signal, the equalization can be carried out by assuming any one of the broadcast signals. Herein, the assumption of the particular signal can vary.

In FIG. 18A, when the signal output from the equalizer 1610 is the cable broadcast signal, the signal passing through the first determiner 1622 can be corrected at the FEC part 1630.

When the input signal to the equalizer 1610 is the terrestrial broadcast signal and the signal passing through the first determiner 1622 is determined as the terrestrial broadcast signal at the second determiner 1624, the error correction can be executed at the FEC part 1630. By contrast, when the input signal to the equalizer 1610 is the terrestrial broadcast signal and the signal passing through the first determiner 1622 is determined as the mobile broadcast signal at the second determiner 1624, a controller (not shown) feeds the input signal of the second determiner 1624 back to the equalizer 1610. Next, the equalizer 1610 fulfils the equalization by assuming the mobile broadcast signal and the controller (not shown) applies the equalized signal directly to the FEC part 1630 to pass through the error correction. It is noted that the controller (not shown) can set that the equalized signal passes through the broadcasting mode determiner 1620 without any operation. The descriptions on the case where the input signal of the equalizer 1610 is the mobile broadcast signal shall be omitted for the brevity.

Unlike FIG. 18A, the second determiner 1624 follows the FEC part 1630 in FIG. 18B. Likewise, the equalizer 1610 performs the equalization by assuming the input signal as a particular broadcast signal, and the first determiner 1622 can determine whether the equalized signal is the cable broadcast signal or not based on the constellation of the signal equalized by the equalizer 1610. Next, when the signal output from the first determiner 1622 is not the cable broadcast signal, the broadcast signal passes through the FEC part 1630 and the second determiner 1624 can determine whether the signal output from the FEC part 1630 is the terrestrial broadcast signal or the mobile broadcast signal using the aforementioned methods.

The signal detector of FIGS. 18A and 18B functions the same as the signal detector of FIGS. 15A and 15B and accordingly its duplicated explanations shall be omitted here.

In contrast to FIGS. 14 through 17, the broadcasting mode determiner 1410 and 1620 can first determine whether the broadcast signal is the mobile broadcast signal, determine whether the broadcast signal is the terrestrial broadcast signal, determine whether the broadcast signal is the cable broadcast signal, and then determine any one of the received multiple broadcast signals.

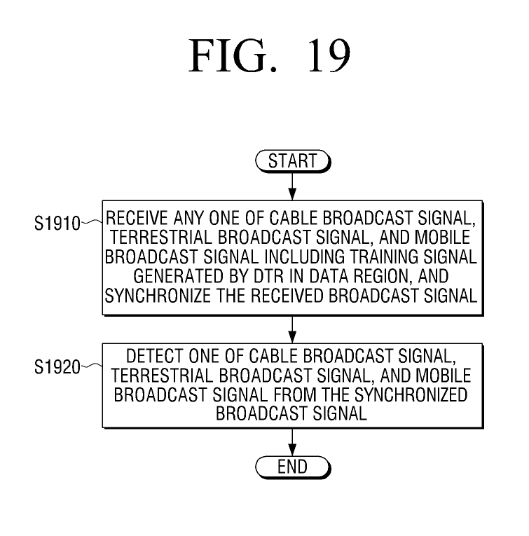

FIG. 19 is a flowchart of a received signal processing method of the common broadcast receiver 100 according to an exemplary embodiment of the present invention. The synchronizer 110 receives any one of the cable broadcast signal, the terrestrial broadcast signal, and the mobile broadcast signal including the training signal generated by the DTR in the data region, and synchronizes the received broadcast signal (S1910). Next, the signal detector 120 detects one of the cable broadcast signal, the terrestrial broadcast signal, and the mobile broadcast signal from the synchronized broadcast signal (S1920). Thus, the common broadcast receiver capable of receiving the mobile broadcast signal together with the cable broadcast signal and the terrestrial broadcast signal, can process the received signals.

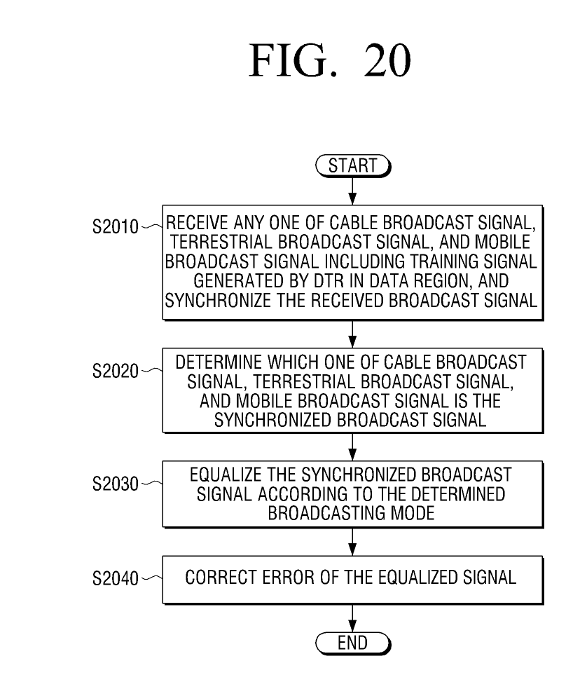

FIG. 20 is a detailed flowchart of the received signal processing method of the common broadcast receiver 100 of FIG. 19. The synchronizer 110 receives any one of the cable broadcast signal, the terrestrial broadcast signal, and the mobile broadcast signal including the training signal generated by the DTR in the data region, and synchronizes the received broadcast signal (S2010).

Next, the broadcasting mode determiner 1410 of the signal detector 120 or 1400 determines which one of the cable broadcast signal, the terrestrial broadcast signal, and the mobile broadcast signal is the synchronized broadcast signal (S2020).

The equalizer 1420 of the signal detector 120 or 1400 equalizes the synchronized broadcast signal according to the determined broadcasting mode (S2030), and the FEC part 1430 of the signal detector 120 or 1400 corrects error of the equalized signal (S2040).

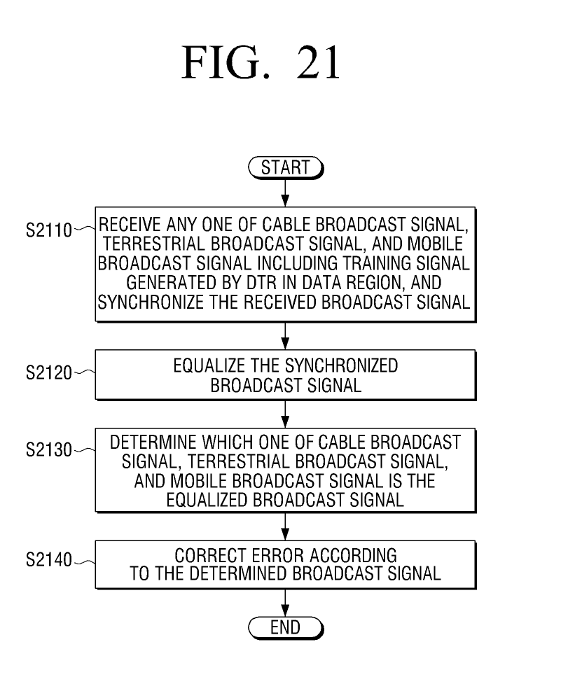

FIG. 21 is a further detailed flowchart of the received signal processing method of the common broadcast receiver 100 of FIG. 19. The synchronizer 110 receives any one of the cable broadcast signal, the terrestrial broadcast signal, and the mobile broadcast signal including the training signal generated by the DTR in the data region, and synchronizes the received broadcast signal (S2110).

The equalizer 1610 of the signal detector 120 or 1600 equalizes the synchronized broadcast signal (S2120).

The broadcasting mode determiner 1620 of the signal detector 120 or 1600 determines which one of the cable broadcast signal, the terrestrial broadcast signal, and the mobile broadcast signal is the equalized broadcast signal (S2130). The FEC part 1630 of the signal detector 120 or 1600 corrects errors according to the determined broadcast signal (S2140).

The embodiments of the present invention can include a computer recording medium containing a program for executing the various broadcast signal processing methods of the common broadcast receiver as set forth above.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A common broadcast receiver for receiving and processing a plurality of broadcast signals, comprising:
a synchronizer configured to receive any one of a cable broadcast signal, a terrestrial broadcast signal, and a mobile broadcast signal comprising a training signal generated by a Deterministic Trellis Reset (DTR) and inserted in a data region, and synchronizes the received broadcast signal; and
a signal detector configured to detect the received broadcast signal from the synchronized broadcast signal.

2. The common broadcast receiver of claim 1, wherein the signal detector comprises:
a broadcasting mode determiner that determines a broadcast mode according to whether the cable broadcast signal, the terrestrial broadcast signal, or the mobile broadcast signal is detected from the synchronized broadcast signal;
an equalizer that equalizes the synchronized broadcast signal according to the determined broadcasting mode; and
a Forward Error Correction (FEC) part that corrects errors in the equalized signal.

3. The common broadcast receiver of claim 2, wherein the equalizer comprises a plurality of equalizers and the FEC part comprises a plurality of FEC parts, and wherein the plurality of equalizers and the plurality of FEC parts correspond to the cable broadcast signal, the terrestrial broadcast signal, and the mobile broadcast signal, respectively.

4. The common broadcast receiver of claim 2, wherein the equalizer and the FEC part comprise a common equalizer and a common FEC part, respectively, that process the cable broadcast signal, the terrestrial broadcast signal, and the mobile broadcast signal all together.

5. The common broadcast receiver of claim 2, wherein the broadcasting mode determiner determines that the synchronized broadcast signal includes the cable broadcast signal if a 1-byte sync signal is repeatedly detected from the synchronized broadcast signal in a preset cycle.

6. The common broadcast receiver of claim 2, wherein the broadcasting mode determiner determines that the synchronized broadcast signal includes the cable broadcast signal if a field sync signal region is not detected from the synchronized broadcast signal.

7. The common broadcast receiver of claim 6, wherein the broadcasting mode determiner determines that the field sync signal region is detected if the synchronized broadcast signal comprises any one of a Pseudo Noise (PN) sequence in a preset form, a Vestigial SideBand (VSB) mode, and a reserved region.

8. The common broadcast receiver of claim 2, wherein the broadcasting mode determiner determines that the synchronized broadcast signal includes the mobile broadcast signal if a training signal is inserted to a data region of the synchronized broadcast signal.

9. The common broadcast receiver of claim 2, wherein the broadcasting mode determiner determines whether the synchronized broadcast signal includes either the terrestrial broadcast signal or the mobile broadcast signal, according to a feature code value in a field sync signal region of the synchronized broadcast signal.

10. The common broadcast receiver of claim 2, wherein the broadcasting mode determiner determines that the synchronized broadcast signal includes the mobile broadcast signal if a PN sequence in a preset size exists in a reserved region of a field sync signal region of the synchronized broadcast signal.

11. The common broadcast receiver of claim 2, wherein the broadcasting mode determiner determines that the synchronized broadcast signal includes the mobile broadcast signal if an FEC coding is performed on symbols of a preset size in a reserved region of a field sync signal region of the synchronized broadcast signal.

12. The common broadcast receiver of claim 2, wherein the broadcasting mode determiner assumes that the synchronized broadcast signal is either the terrestrial broadcast signal or the mobile broadcast signal, outputs an error-corrected signal if the error-corrected signal is a normal signal, and if the error-corrected signal is an error signal, modifies the assumption and carries out the equalization and the error correction in order.

13. The common broadcast receiver of claim 1, wherein the signal detector comprises:
an equalizer that equalizes the synchronized broadcast signal;
a broadcasting mode determiner that determines a broadcast mode according to whether the cable broadcast signal, the terrestrial broadcast signal, or the mobile broadcast signal is included in the equalized broadcast signal; and
an FEC part that corrects errors according to the determined broadcast mode.

14. The common broadcast receiver of claim 13, wherein the broadcasting mode determiner determines whether the equalized broadcast signal includes the cable broadcast signal according to a constellation of the equalized broadcast signal.

15. The common broadcast receiver of claim 13, wherein the broadcasting mode determiner determines that the equalized broadcast signal includes the cable broadcast signal if a 1-byte sync signal is repeatedly detected from the equalized broadcast signal in a preset cycle.

16. The common broadcast receiver of claim 13, wherein the broadcasting mode determiner determines that the equalized broadcast signal includes the cable broadcast signal if a field sync signal region is not detected from the equalized broadcast signal.

17. The common broadcast receiver of claim 16, wherein the broadcasting mode determiner determines that the field sync signal region is detected, if the equalized broadcast signal comprises any one of a PN sequence in a preset form, a VSB mode, and a reserved region.

18. The common broadcast receiver of claim 13, wherein the broadcasting mode determiner determines that the equalized broadcast signal includes the mobile broadcast signal if a training signal is inserted to a data region of the equalized broadcast signal.

19. The common broadcast receiver of claim 13, wherein the broadcasting mode determiner determines whether the equalized broadcast signal includes either the terrestrial broadcast signal or the mobile broadcast signal, according to a feature code value in a field sync signal region of the equalized broadcast signal.

20. The common broadcast receiver of claim 13, wherein the broadcasting mode determiner determines that the equalized broadcast signal includes the mobile broadcast signal if a PN sequence of a preset size exists in a reserved region of a field sync signal region of the equalized broadcast signal.

21. The common broadcast receiver of claim 13, wherein the broadcasting mode determiner determines that the equalized broadcast signal includes the mobile broadcast signal if an FEC coding is performed on symbols of a preset size in a reserved region of a field sync signal region of the equalized broadcast signal.

22. The common broadcast receiver of claim 13, wherein the broadcasting mode determiner assumes that the equalized broadcast signal is either the terrestrial broadcast signal or the mobile broadcast signal, outputs an error-corrected signal if the error-corrected signal is a normal signal, and, if the error-corrected signal is an error signal, modifies the assumption and carries out the equalization and the error correction in order.

23. A method for processing a received signal of a common broadcast receiver which receives and processes a plurality of broadcast signals, comprising:
receiving any one of a cable broadcast signal, a terrestrial broadcast signal, and a mobile broadcast signal comprising a training signal generated by a Deterministic Trellis Reset (DTR) and inserted in a data region, and synchronizing the received broadcast signal; and
detecting the received broadcast signal from the synchronized broadcast signal.

24. The method of claim 23, wherein the detecting operation comprises:
determining a broadcast mode according to the cable broadcast signal, the terrestrial broadcast signal, or the mobile broadcast signal is detected from the synchronized broadcast signal;
equalizing the synchronized broadcast signal according to the determined broadcasting mode; and
correcting errors in the equalized signal.

25. The method of claim 24, wherein the determining operation determines that the synchronized broadcast signal includes the cable broadcast signal if a 1-byte sync signal is repeatedly detected from the synchronized broadcast signal in a preset cycle.

26. The method of claim 24, wherein the determining operation determines that the synchronized broadcast signal includes the cable broadcast signal if a field sync signal region is not detected from the synchronized broadcast signal.

27. The method of claim 26, wherein the determining operation determines that the field sync signal region is detected if the synchronized broadcast signal comprises any one of a PN sequence in a preset form, a VSB mode, and a reserved region.

28. The method of claim 24, wherein the determining operation determines that the synchronized broadcast signal includes the mobile broadcast signal if a training signal is inserted to a data region of the synchronized broadcast signal.

29. The method of claim 24, wherein the determining operation determines whether the synchronized broadcast signal includes either the terrestrial broadcast signal or the mobile broadcast signal, according to a feature code value in a field sync signal region of the synchronized broadcast signal.

30. The method of claim 24, wherein the determining operation determines that the synchronized broadcast signal includes the mobile broadcast signal if a PN sequence in a preset size exists in a reserved region of a field sync signal region of the synchronized broadcast signal.

31. The method of claim 24, wherein the determining operation determines that the synchronized broadcast signal includes the mobile broadcast signal if an FEC coding is performed on symbols of a preset size in a reserved region of a field sync signal region of the synchronized broadcast signal.

32. The method of claim 24, wherein the determining operation assumes that the synchronized broadcast signal is either the terrestrial broadcast signal or the mobile broadcast signal, outputs an error-corrected signal if the error-corrected signal is a normal signal, and if the error-corrected signal is an error signal, modifies the assumption and carries out the equalization and the error correction in order.

33. The method of claim 24, wherein the detecting operation comprises:
equalizing the synchronized broadcast signal;
determining a broadcast mode according to whether the cable broadcast signal, the terrestrial broadcast signal, or the mobile broadcast signal is included in the equalized broadcast signal; and
correcting errors according to the determined broadcast mode.

34. The method of claim 33, wherein the determining operation determines whether or not the equalized broadcast signal is the cable broadcast signal according to a constellation of the equalized broadcast signal.

35. The method of claim 33, wherein the determining operation determines that the equalized broadcast signal includes the cable broadcast signal if a 1-byte sync signal is repeatedly detected from the equalized broadcast signal in a preset cycle.

36. The method of claim 33, wherein the determining operation determines that the equalized broadcast signal includes the cable broadcast signal if a field sync signal region is not detected from the equalized broadcast signal.

37. The method of claim 36, wherein the determining operation determines that the field sync signal region is detected, if the equalized broadcast signal comprises any one of a PN sequence in a preset form, a VSB mode, and a reserved region.

38. The method of claim 33, wherein the determining operation determines that the equalized broadcast signal includes the mobile broadcast signal if a training signal is inserted to a data region of the equalized broadcast signal.

39. The method of claim 33, wherein the determining operation determines whether the equalized broadcast signal is either the terrestrial broadcast signal or the mobile broadcast signal, according to a feature code value in a field sync signal region of the equalized broadcast signal.

40. The method of claim 33, wherein the determining operation determines that the equalized broadcast signal includes the mobile broadcast signal if a PN sequence of a preset size exists in a reserved region of a field sync signal region of the equalized broadcast signal.

41. The method of claim 33, wherein the determining operation determines that the equalized broadcast signal includes the mobile broadcast signal if an FEC coding is performed on symbols of a preset size in a reserved region of a field sync signal region of the equalized broadcast signal.

42. The method of claim 33, wherein the determining operation assumes that the equalized broadcast signal is either the terrestrial broadcast signal or the mobile broadcast signal, outputs an error-corrected signal if the error-corrected signal is a normal signal, and if the error-corrected signal is an error signal, modifies the assumption and carries out the equalization and the error correction in order.
